(19) United States
(12) Patent Application Publication
(10) Pub. No.: US 2026/0304682 A1
(43) Pub. Date: Oct. 1, 2026

(54) ELECTRONIC DEVICE WITH ACTIVE COOLING

(71) Applicant: UBICQUIA, INC., FORT LAUDERDALE, FL (US)

(72) Inventors: Claudio Santiago Ribeiro, Evanston, IL (US); Cesar Eduardo Nunez, Miramar, FL (US); Elliott Earl Murray, Plantation, FL (US); Carlos Julio Suate Pedroza, Miramar, FL (US)

(21) Appl. No.: 19/633,933

(22) Filed: Mar. 30, 2026

Related U.S. Application Data
(60) Provisional application No. 63/781,296, filed on Mar. 31, 2025.

(51) Int. Cl. H05K 7/20

(52) U.S. Cl. CPC H05K 7/20145; H05K 7/2039

(57) ABSTRACT

An electronic device includes top and bottom housing members, one or more fans, and one or more heat-generating electrical modules. The top housing member includes one or more air vents. The bottom housing member includes a floor portion and a finned heat sink, where the floor portion includes one or more air ducts to direct air across fins of the heat sink. Each fan is positioned between an air vent and an air duct and operable to draw air in through the air vent and force air out into the air duct for flow over the heat sink fins. The top housing member may also define one or more pockets for receiving the fan(s), where each pocket is positioned between an air vent and an air duct. Forced air from a fan may be redirected by an air duct before being exhausted over and along the heat sink fins.

### CROSS-REFERENCE TO RELATED APPLICATIONS

The present application claims the benefit of and priority upon U.S.

Provisional Patent Application No. 63/781,296, which was filed on Mar. 31, 2025, and is incorporated herein by this reference as if fully set forth herein.

### TECHNICAL FIELD

The present disclosure relates generally to electronic devices that include processors, transmitters, power supplies, or other heat-generating electronics. More particularly, the present disclosure relates to an electronic device with active cooling to assist in providing adequate cooling for heat-generating elements of the device.

### BACKGROUND

In the electronics field, active cooling typically refers to using one or more fans to assist in reducing the temperature of electrical or electronic components or modules, such as processors, transmitters, power supplies, or other heat-generating electronics, by forcing or blowing cool or ambient air over or along fins of one or more heat sinks to which the electronic components are thermally coupled. In the case of an electronic device exposed to the environment, several considerations, such as exposure to dust, debris, and wildlife, must be taken into account when selecting an appropriate active cooling implementation for the electronic device. Where the electronic device is also to be connected to and powered from an outdoor lighting fixture, additional complications arise when attempting to properly cool the electronic device.

### SUMMARY

According to some exemplary embodiments of the present disclosure, an electronic device includes a top housing member, a bottom housing member, a fan, and at least one heat-generating electrical module (e.g., one or more electrical circuits containing heat-generating electrical components or one or more such electrical circuits on one or more substrates, such as one or more printed circuit boards). The top housing member includes an air vent. The bottom housing member includes a floor portion and a finned heat sink. The floor portion of the bottom housing member includes an air duct to direct air over fins of the heat sink. The fan is positioned between the air vent and the air duct and operable to draw air in through the air vent and force air out into the air duct for flow over the fins of the heat sink. The electrical module(s) is thermally coupled to a base of the heat sink and operable to generate heat during operation. The heat sink may be secured to or integrated with the floor of the bottom housing member.

In some exemplary embodiments, the top housing member may be covered by a permanent or removable cover. In such a case, the cover may include a vent to allow the fan to draw ambient air under the cover and into the top housing member's air vent.

In other exemplary embodiments, the top housing member may define or include a slot or pocket for receiving the fan, where the pocket is positioned between the air vent and the air duct. The top housing member may also or alternatively include a set of louvers positioned proximate to an entry of the air vent, where the set of louvers serves as an air guide and a fan protector.

In further exemplary embodiments, the electronic device further includes a fan cover plate positioned between the fan and the air duct to maximize a flow of forced air from the fan into the air duct. In some such embodiments, the fan cover plate defines an aperture sized and shaped to match the geometry of an output of the fan.

In other exemplary embodiments, the air duct is at least partially formed as a recess within the floor portion of the bottom housing member.

In further exemplary embodiments, the air duct has an exhaust port aligned with the fins of the heat sink. In such embodiments, the exhaust port allows forced air from the fan to flow over the heat sink fins, which may be formed longitudinally on an underside or external surface of the bottom housing member. Such arrangement permits a low profile structure for the electronic device.

In other exemplary embodiments,. the fan is positioned so as to draw air in vertically through the air vent and force air out vertically into the air duct. For example, the fan may be positioned below the air vent and above the air duct. Additionally, the air duct may be configured to receive the air vertically from the fan and direct the received air horizontally to flow over the fins of the heat sink. More generally, the air duct may be configured to receive air from the fan from a first direction and direct or redirect the received air in a second direction that is not collinear with the first direction so as to flow over the fins of the heat sink. In other words, the air duct may be configured to change the outflow direction of the received air. For example, the air duct may be configured to direct the forced air from the fan in a direction that is substantially orthogonal to the direction from which the forced air entered the air duct.

In further exemplary embodiments, the electronic device may be mountable to a streetlight, outdoor lighting fixture, or other structure. Where the electronic device is mountable to a streetlight or other roadway or parking lot lighting fixture, the electronic device may include a standardized connector (e.g., plug) that mates with a complementary connector (e.g., socket) located atop the luminaire of the streetlight to enable the electronic device to receive AC power from the streetlight.

According to other exemplary embodiments of the present disclosure, an electronic device includes a top housing member, a bottom housing member, a plurality of fans, and at least one heat-generating electrical module (e.g., one or more electrical circuits or one or more electrical circuits on one or more substrates, such as printed circuit boards). The top housing member includes a plurality of air vents (e.g., an air vent on each lengthwise side). The bottom housing member includes a floor portion and a finned heat sink. The floor portion of the bottom housing member includes a plurality of air ducts to direct air over fins of the heat sink. The fans are positioned between the air vents and the air ducts such that each fan is operable to draw air in through a respective air vent and force air out into a respective air duct for flow over the fins of the heat sink. The electrical module(s) is thermally coupled to a base of the heat sink and operable to generate heat during operation. The heat sink may be secured to or integrated with the floor of the bottom housing member.

In some exemplary embodiments, the top housing member may be covered by a permanent or removable cover. In such a case, the cover may have a plurality of vents to allow the fans to draw ambient air under the cover and into the top housing member's air vents.

In other exemplary embodiments, the top housing member may define or include a plurality of slots or pockets for receiving the fans, where each pocket is positioned between an air vent and an air duct and configured to receive a respective fan. The top housing member may also or alternatively include a set of louvers positioned proximate to an entry of the air vent, where the set of louvers serves as an air guide and a fan protector.

In further exemplary embodiments, the electronic device also includes a fan cover plate positioned between the fans and the air ducts to maximize a flow of forced air from the fans into the air ducts. In some such embodiments, the fan cover plate defines a plurality of apertures, where each aperture is sized and shaped to match the geometry of an output of a respective fan.

In other exemplary embodiments, the air ducts are formed wholly or partially as recesses within the floor portion of the bottom housing member.

In further exemplary embodiments, the air ducts share a common exhaust port aligned with the fins of the heat sink. In such embodiments, the exhaust port allows forced air from the fans to flow over the heat sink fins, which may be formed longitudinally on an underside or external surface of the bottom housing member. Such arrangement permits a lower profile structure for the electronic device.

In other exemplary embodiments, each fan is positioned so as to draw air in vertically through a respective air vent and force air out vertically into a respective air duct. For example, each fan may be positioned below its respective air vent and above its respective air duct. Additionally, each air duct may be configured to receive the air vertically from its associated fan and direct or redirect the received air horizontally to flow over the fins of the heat sink. More generally, each air duct may be configured to receive air from an associated fan from a first direction and direct the received air in a second direction that is not collinear with the first direction so as to flow over the fins of the heat sink. In other words, each air duct may be configured to change the outflow direction of its received air. For example, each air duct may be configured to direct the forced air from an associated fan in a direction that is substantially orthogonal to the direction from which the forced air entered the air duct.

According to other exemplary embodiments of the present disclosure, an electronic device includes a top housing member, a bottom housing member, a fan, and at least one heat-generating electrical module (e.g., one or more electrical circuits or one or more electrical circuits on one or more substrates, such as one or more printed circuit boards). The top housing member includes an air vent and a fan slot or pocket adjacent to the air vent. The bottom housing member includes a floor portion and a finned heat sink. The floor portion of the bottom housing member includes an air duct to direct air over the fins of the heat sink, where the heat sink fins are externally exposed on an outside surface of the bottom housing member. The fan is positioned in the fan pocket between the air vent and the air duct and is operable to draw air in through the air vent and force air out into the air duct for flow over the fins of the heat sink. The electrical module(s) is thermally coupled to a base of the heat sink and operable to generate heat during operation. The heat sink may be secured to or integrated with the floor of the bottom housing member.

In some embodiments, when the top housing member and the bottom housing member are secured together, the housing members define a sealed chamber or main compartment within which the electrical module(s) resides while transferring heat outside the chamber through the fins of the heat sink.

### BRIEF DESCRIPTION OF THE DRAWINGS

Non-limiting and non-exhaustive embodiments are described with reference to the following drawings, wherein like reference numerals refer to like parts or elements throughout the various views unless otherwise specified. The sizes and relative positions of elements in the drawings are not necessarily drawn to scale. For example, the shapes of various elements are selected, enlarged, and positioned to improve drawing legibility and understandability. The particular shapes of the elements as drawn have been selected for ease of recognition in the drawings.

FIG. 1 illustrates an exploded view of an exemplary electronic device with active cooling in accordance with some embodiments of the present disclosure.

FIG. 2 illustrates airflow through the electronic device of FIG. 1 in accordance with some exemplary embodiments of the present disclosure.

FIG. 3A illustrates a bottom perspective view of the electronic device of FIG. 1 in assembled form in accordance with some exemplary embodiments of the present disclosure.

FIG. 3B illustrates a bottom view of the electronic device of FIG. 3A.

FIG. 3C illustrates a cutaway view along line C-C of FIG. 3B.

FIG. 4A is a top, left, perspective view of the electronic device of FIG. 1 in assembled form in accordance with some exemplary embodiments of the present disclosure.

FIG. 4B is a left side view of the electronic device of FIG. 4A.

FIG. 4C is a rear view of the electronic device of FIG. 4A.

FIG. 4D is a top view of the electronic device of FIG. 4A.

FIG. 4E is a front view of the electronic device of FIG. 4A.

FIG. 5 illustrates a perspective view of the electronic device of FIG. 1 in a position of exemplary use as attached to a streetlight luminaire in accordance with some exemplary embodiments of the present disclosure.

### DETAILED DESCRIPTION

In the following description, certain specific details are set forth in order to provide an understanding of various disclosed embodiments. However, one skilled in the relevant art will recognize that embodiments may be practiced without one or more of these specific details, or with other methods, components, materials, etc. Additionally, well-known structures may be omitted or shown and described in reduced detail to avoid unnecessarily obscuring descriptions of exemplary embodiments.

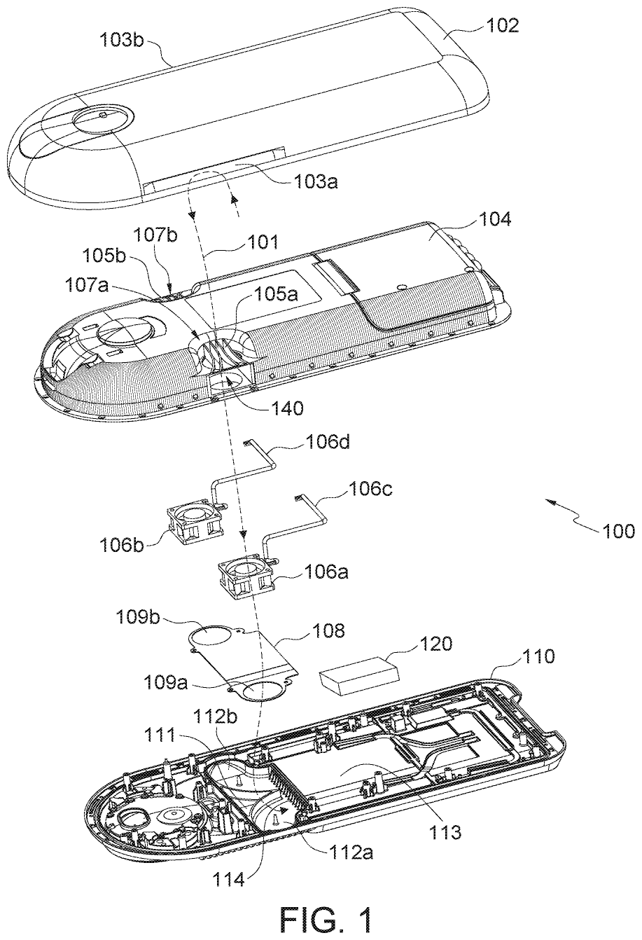

According to some embodiments and with reference to FIGS. 1-4E, an electronic device 100 includes a top housing member 104, a bottom housing member 110, one or more fans 106a, 106b (two shown for illustration purposes), and one or more heat-generating electrical or electronic modules 120 (one shown for illustration purposes). The top housing member 104 includes one or more air vents 107a, 107b (two shown for illustration purposes) and the bottom housing member 110 includes a floor portion 111 and a finned heat sink 113. A section of the floor portion 111 includes one or more air ducts 112a, 112b (two shown for illustration purposes) to direct air across fins 114 of the heat sink 113. Each fan 106a, 106b is positioned between a respective air vent 107a, 170b and a respective air duct 112a, 112b and is operable to draw air in through the air vent 107a, 107b and force air out into the air duct 112a, 112b for flow over the fins 114 of the heat sink 113. The electrical or electronic module(s) 120 may include a processor, transmitter, amplifier, power supply, or other heat generating electrical module (e.g., an electrical circuit as fabricated on a substrate, such as a printed circuit board, which may may or may not include its own separate housing or enclosure) and is thermally coupled to a base of the heat sink 113. In some embodiments, the base of the heat sink 113 is integrated with and forms part of another section of the floor portion 111 of the bottom housing member 110. Thermal coupling between the electrical module(s) 120 and the heat sink base may be achieved using any known thermal coupling technology, including fasteners, thermal pads, thermal tape, thermal paste, and/or other known means.

The determination of whether to use one fan (106a or 106b) or a plurality of fans 106a, 106b in the electronic device's active cooling implementation depends on a variety of factors, including the amount of heat being generated by the electrical module(s) 120 and other sources of heat near the location at which the electronic device 100 will be installed or used, the size of the electronic device 100, the amount of available floor space for integration or inclusion of a heat sink 113, the environment in which the electronic device 100 will be used (e.g., in an air conditioned building or on an outdoor streetlight), and so forth. The disclosed active cooling configuration is usable with a single forced air flow path or multiple forced air flow paths.

In some embodiments, the top housing member 104 may be configured to receive a permanent or removable cover 102 having one or more vents or other openings 103a, 103b (two shown for illustration purposes) to permit ambient air to be drawn under the cover 102 and into the top housing member's air vents 107a, 107b by the fans 106a, 106b. The top housing member 104 may also or alternatively include one or more slots or pockets 140 (one shown for illustration purposes) for receiving the fans 106a, 106b and positioning them between the air vents 107a, 107b and their associated air ducts 112a, 112b. In some embodiments, the top housing member 104 optionally includes a set of louvers 105a, 105b positioned proximate to the entry of the air vents 107a, 107b that serves as an air guide and a protector for the fans 106a, 106b. Each fan 106a, 106b may include or be connected to a respective wire or cable 106c, 106d to receive power from a power supply (not shown) within the electronic device 100.

In some embodiments, the electronic device 100 optionally includes a fan cover plate 108 positioned between the fan 106a, 106b and its associated air duct 112a, 112b to maximize a flow of forced air from the fan 106a, 106b into the air duct 112a, 112b. In such embodiments, the fan cover plate 108 defines one or more apertures 109a, 109b (e.g., one aperture 109a when one fan 106a is used, two apertures 109a, 109b when two fans 106a, 106b are used, etc.) sized and shaped to match the geometries (e.g., circle, oval, rectangle, etc.) of the housing outlets of the fans 106a, 106b.

Each air duct 112a, 112b may be formed from one or more separate parts that are fastened to the bottom housing member 110. Alternatively, as illustrated in FIGS. 1-3C, each air duct 112a, 112b may be wholly or partially formed as a recess within the floor portion 111 of the bottom housing member 110. In some exemplary embodiments, including the embodiment illustrated in FIGS. 1-4E, the air ducts 112a, 112b share a common exhaust port 115 aligned with the fins 114 of the heat sink 113 to allow forced air from the fans 106a, 106b to exit the air ducts 112a, 112b and flow over and along the heat sink fins 114. Alternatively, each air duct 112a, 112b may have or use its own exhaust port to allow forced air from its associated fan 106a, 106b to exit the air duct 112a, 112b and flow over and along some or all of the fins 114 of the heat sink 113. As illustrated in FIGS. 1-3C, the heat sink fins 114 may be formed to run longitudinally on an underside or external surface of the bottom housing member 110. Such arrangement permits a lower profile structure for the electronic device 100.

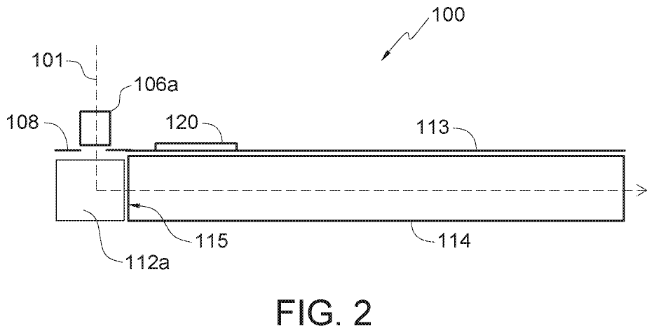

With further reference to FIGS. 1 and 2, the dashed line 101 represents the air flow through various elements of the exemplary electronic device 100. As the dashed line 101 shows, ambient air is drawn into a vent 107 a of the top housing member 104 (optionally through a vent 103a in the cover 102, when the cover 102 is used) by a fan 106a and then forced out of the fan 106a into its associated air duct 112a (or into a common air duct where a single air duct supports both fan outputs), which directs the air through the exhaust port 115 and over the fins 114 of the heat sink 113. In this manner, the forced air cools the fins 114 of the heat sink 113 as the heat sink 113 draws heat generated by the electrical module 120 (and elsewhere) away from the electrical module 120. As previously noted, the electrical module 120 is thermally coupled to the base of the heat sink 113.

According to some exemplary embodiments, including the embodiment illustrated in FIGS. 1-3C, each fan 106a, 106b is positioned below a respective air vent 107a, 107b and above a respective air duct 112a, 112b. In such embodiments, each fan 106a, 106b is operable to draw air vertically in through the respective air vent 107a, 107b and force air vertically outward into the respective air duct 112a, 112b. Additionally, each air duct 112a, 112b may be configured, as are the air ducts 112a, 112b illustrated in FIGS. 1-3C, to receive the forced air vertically from its associated fan 106a, 106b and direct the received air horizontally to flow over and along the fins 114 of the heat sink 113. More generally, each air duct 112a, 112b may be configured to receive air from an associated fan 106a, 106b from a first direction (e.g., vertically) and direct the received air over the fins 114 of the heat sink 113 in a second direction (e.g., horizontally) that is not collinear with the first direction. In other words, each air duct 112a, 112b may be configured to change the outflow direction of its received air as compared to the inflow direction. For example, each air duct 112a, 112b may be configured to direct the forced air from an associated fan 106a, 106b in a direction that is substantially orthogonal to the direction from which the forced air entered the air duct 112a, 112b, such as is shown in the embodiment illustrated in FIGS. 1-3C. Alternatively, in appropriate situations, an air duct 112a, 112b may direct the received air from the fan 106a, 106b in the same direction (e.g., collinearly) as the direction from which the air was received (e.g., downwardly, upwardly, or otherwise, as the case may be).

In some exemplary embodiments, a floor portion of the air duct 112a, 112b and bottom portions of the fins 114 of the heat sink 113 are substantially on the same plane. In such embodiments, the floor portion 111 of the bottom housing member 110 resides on one plane and the recessed floor portion of the air duct 112a, 112b resides on a different plane (which may be parallel to the plane of the floor portion 111), thereby forming a gap to create the exhaust port 115. The exhaust port 115 aligns with the fins 114 of the heat sink 113, which may reside on an external surface of the bottom housing member 110 in such embodiments.

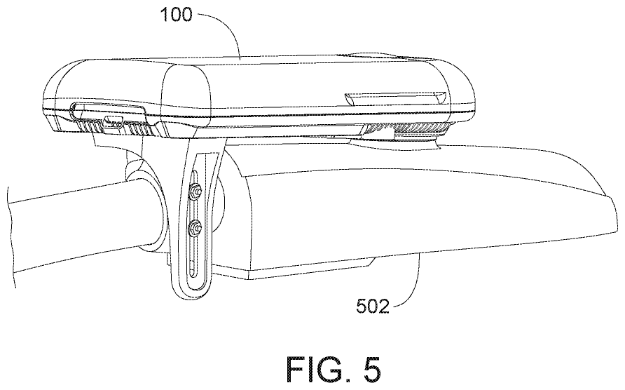

In some exemplary embodiments, the electronic device 100 may be mountable to a streetlight or other structure. Where the electronic device 100 is mountable to a streetlight, such as is shown in FIG. 5, the electronic device 100 may include a standardized connector 130 (e.g., a plug connector that complies with ANSI C136.41) that mates with a complementary connector (e.g., a socket connector that complies with ANSI C136.41) located atop a luminaire 502 of the streetlight to enable the electronic device 100 to receive alternating current (AC) power from the streetlight.

According to exemplary embodiments in which the electronic device 100 includes multiple fans 106a, 106b in its active cooling configuration, the top housing member 104 has or includes a plurality of air vents 107a, 107b, and the bottom housing member 110 includes a floor portion 111 and a finned heat sink 113, where the floor portion 111 includes a plurality of air ducts 112a, 112b to direct air over and along fins 114 of the heat sink 113. In embodiments in which the top cover 102 is also used, the cover 102 includes one or more vents 103a, 103b to allow the fans 106a, 106b to draw ambient air under the cover and into the top housing member's vents 107a, 107b. In all exemplary embodiments disclosed herein, the vents 107a, 107b of the top housing member 104 or the vents 103a, 103b of the cover 102 (when used) may be configured to prevent or mitigate moisture or debris from entering the fans 106a, 106b, including through use of louvers 105a, 105b, meshing, or other debris and moisture blocking design approaches.

In some multi-fan embodiments, the electronic device 100 also includes a fan cover plate 108 defining a plurality of apertures 109a, 109b, where each aperture 109a, 109b is sized and shaped to match the geometry of a respective fan output. In other multi-fan embodiments, the air ducts 112a, 112b may share a common exhaust port 115 aligned with the heat sink fins 114 to enable the air forced into the air ducts 112a, 112b to exit through the exhaust port 115 and flow over the heat sink fins 114.

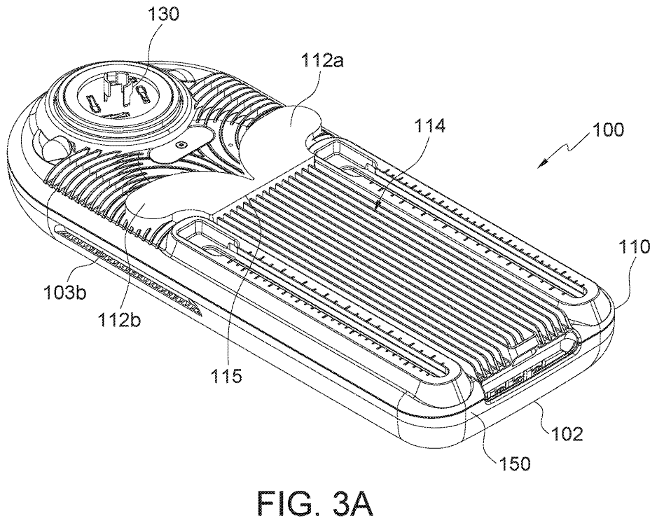

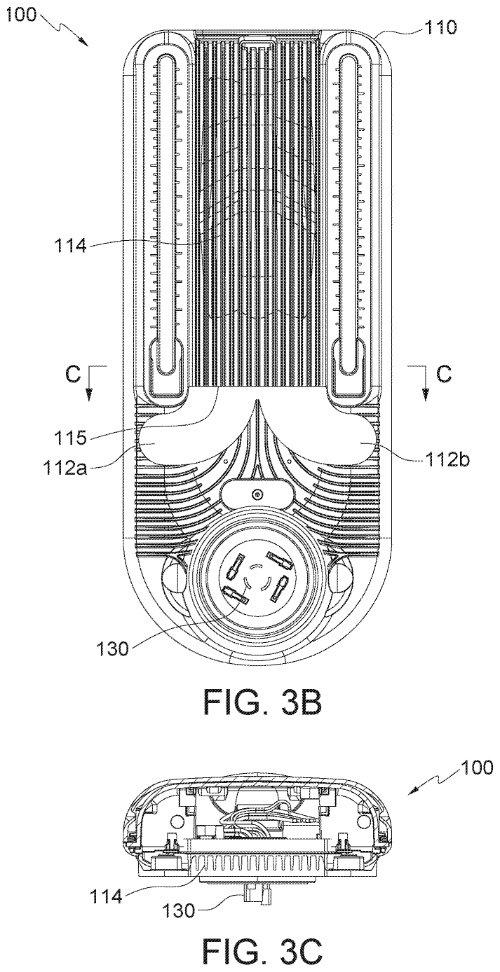

According to other exemplary multi-fan embodiments, including the embodiment illustrated in FIGS. 1 and 3A-3C, each fan 106a, 106b is positioned (e.g., into a corresponding fan slot or pocket 140) adjacent and below a respective air vent 107a, 107b and above a respective air duct 112a, 112b. In such embodiments, each fan 106a, 106b is operable to draw air in vertically through the respective air vent 107a, 107b and force air out vertically into the respective air duct 112a, 112b. Additionally, each air duct 112a, 112b may be configured, as are the air ducts 112a, 112b illustrated in FIGS. 1 and 3A-3C, to receive the air vertically from its associated fan 106a, 106b and direct the received air horizontally out the exhaust port 115 to flow over and along the fins 114 of the heat sink 113. More generally, each air duct 112a, 112b may be configured to receive air from an associated fan 106a, 106b from a first direction (e.g., vertically) and direct the received air out of the exhaust port 115 and over or across the fins 114 of the heat sink 113 in a second direction (e.g., horizontally) that is not collinear with the first direction. In other words, each air duct 112a, 112b may be configured to change the outflow direction of its received air. For example, each air duct 112a, 112b may be configured to direct the forced air from an associated fan 106a, 106b in a direction that is substantially orthogonal to the direction from which the forced air entered the air duct 112a, 112b, such as is shown in FIGS. 1 and 2. Alternatively, in appropriate situations, one or more of the air ducts 112 a, 112 b may direct air received from its associated fan 106a, 106b in the same direction (e.g., collinearly) as the direction from which the air was received (e.g., downwardly, upwardly, or otherwise, as the case may be).

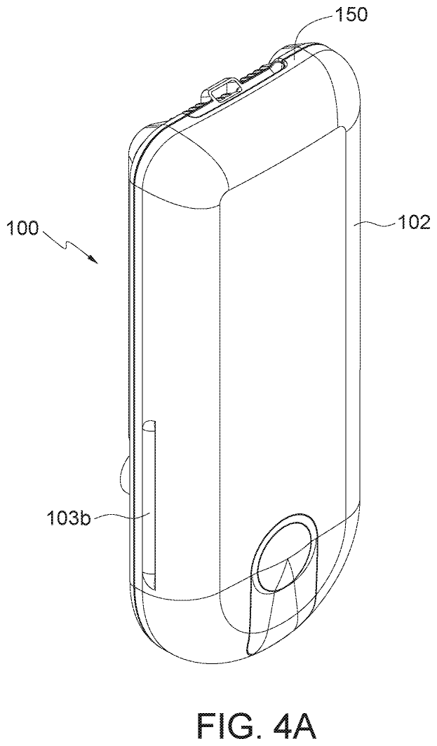

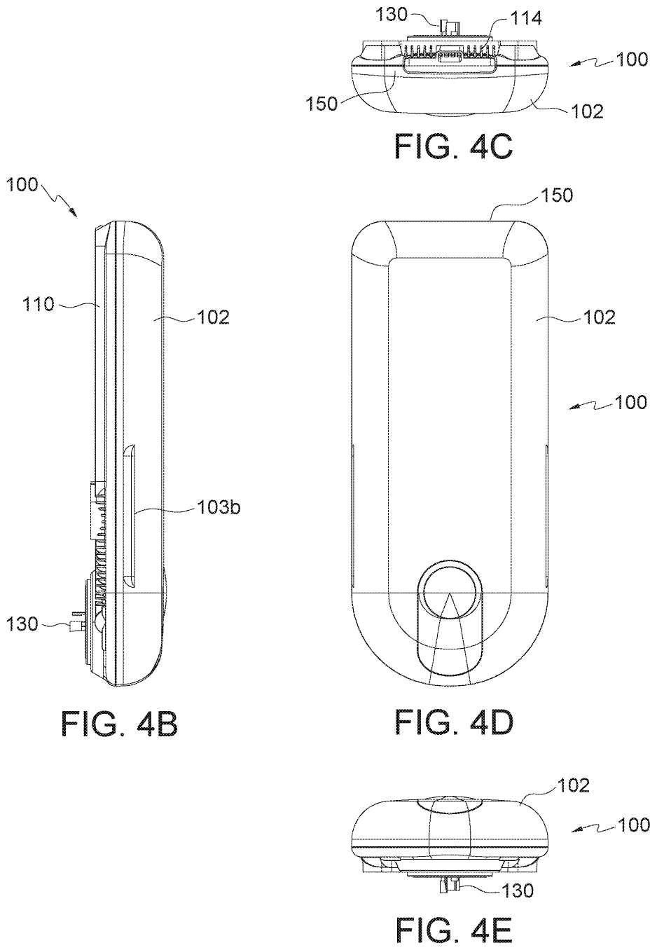

FIGS. 4A-4E illustrate various views of the exemplary electronic device 100 of FIGS. 1 and 3A-3C in assembled form. The view shown in FIG. 4C illustrates the externally exposed portions of the fins 114 of the heat sink 113 from the rear 150 of the electronic device 110. According to the exemplary embodiments illustrated in FIGS. 1 and 3A-4E, the fins 114 of the heat sink 113 are externally exposed on an outside surface of the bottom housing member 110, but in other embodiments, such may not be the case (e.g., only portions of the heat sink fins 114 may be exposed or no portions of the heat sink fins 114 may be exposed).

In some multi-fan embodiments, when the top housing member 104 and the bottom housing member 110 are secured together, the housing members 104, 110 define a sealed chamber or main compartment within which the electrical module(s) 120 resides while transferring heat outside the chamber through the fins 114 of the heat sink 113.

In some exemplary embodiments, as illustrated in FIG. 5, the electronic device 100 may be mountable to a streetlight by being electrically connected to the topside electrical socket of the streetlight's luminaire 502 and optionally mechanically secured to the streetlight pole, such as with a clamp. In such embodiments, the electronic device 100 may perform streetlight control functions, provide a computing platform for performing public safety functions, operate as a wireless system small cell or repeater, monitor power quality at the streetlight, and/or perform other functions.

In the absence of any specific clarification related to its express use in a particular context, where the term “substantial” or “about” in any grammatical form is used as a modifier in the present disclosure and any appended claims (e.g., to modify a structure, a dimension, a measurement, a direction, or any other characteristic), such term means that the so-modified characteristic may vary by up to thirty percent. For example, forced air received into an air duct from a first direction and directed out of the air duct in a second, substantially orthogonal direction permits the angle between the first direction and second direction to vary by up to thirty percent from true orthogonality (i.e., for such example, the angle between the two directions is in the range of 63 degrees to 117 degrees).

The terms “include” and “comprise,” as well as derivatives thereof, in all of their syntactic contexts, are to be construed without limitation in an open, inclusive sense, (e.g., “including, but not limited to”). The term “or” is inclusive, meaning “and/or.” The phrases “associated with” and “associated therewith,” as well as derivatives thereof, can be understood as meaning to include, be included within, interconnect with, contain, be contained within, connect to or with, couple to or with, be communicable with, cooperate with, interleave, juxtapose, be proximate to, be bound to or with, have, have a property of, or the like.

Reference throughout this specification to “one embodiment” or “an embodiment” or “some embodiments” and variations thereof mean that a particular feature, structure, or characteristic described in connection with the embodiment is included in at least one embodiment. Thus, the appearances of the phrases “in one embodiment,” “in an embodiment,” or “in some embodiments” in various places throughout this specification are not necessarily all referring to the same embodiment. Furthermore, particular features, structures, or characteristics described in the present disclosure may be combined in any suitable manner in one or more embodiments.

As used in this specification and the appended claims, the singular forms “a,” “an,” and “the” include plural referents unless the content and context clearly dictates otherwise. It should also be noted that the conjunctive and disjunctive terms, “and” and “or,” are generally employed in this disclosure in the broadest sense and should be interpreted as “and/or” unless the content and context clearly dictates otherwise. In addition, the composition of “and” and “or” when recited herein as “and/or” is intended to encompass an embodiment that includes all of the associated items and one or more other alternative embodiments that include fewer than all of the associated items.

Unless the context requires otherwise, the singular shall mean the plural and vice versa in the present disclosure. The various embodiments described above can be combined together or with other components or materials to provide further embodiments.

What is claimed is:

1. An electronic device comprising:
a top housing member including an air vent;
a bottom housing member including a floor portion and a finned heat sink, the floor portion including an air duct to direct air over fins of the heat sink;
a fan positioned between the air vent and the air duct and operable to draw air in through the air vent and force air out into the air duct for flow over the fins of the heat sink; and
at least one electrical module thermally coupled to a base of the heat sink and operable to generate heat during operation.

2. The electronic device of claim 1, wherein the top housing member defines a pocket for receiving the fan, the pocket being positioned between the air vent and the air duct.

3. The electronic device of claim 1, wherein the top housing member further includes a set of louvers that serves as an air guide and a fan protector, the set of louvers being positioned proximate to an entry of the air vent.

4. The electronic device of claim 1, further comprising:
a fan cover plate positioned between the fan and the air duct to maximize a flow of forced air from the fan into the air duct.

5. The electronic device of claim 4, wherein the fan cover plate defines an aperture sized and shaped to match a geometry of an output of the fan.

6. The electronic device of claim 1, wherein the air duct has an exhaust port aligned with the fins of the heat sink.

7. The electronic device of claim 1, wherein the fan is positioned so as to draw air in vertically through the air vent and force air out vertically into the air duct.

8. The electronic device of claim 7, wherein the air duct is configured to receive the air vertically from the fan and direct the received air horizontally to flow over the fins of the heat sink.

9. The electronic device of claim 1, wherein the air duct is configured to receive air from the fan from a first direction and direct the received air in a second direction that is not collinear with the first direction so as to flow over and along the fins of the heat sink.

10. The electronic device of claim 9, wherein the second direction is substantially orthogonal to the first direction.

11. An electronic device comprising:
a top housing member including a plurality of air vents;
a bottom housing member including a floor portion and a finned heat sink, the floor portion including a plurality of air ducts to direct air over fins of the heat sink;
a plurality of fans positioned between the plurality of air vents and the plurality of air ducts, each fan operable to draw air in through a respective air vent and force air out into a respective air duct for flow over the fins of the heat sink; and
at least one electrical module thermally coupled to a base of the heat sink and operable to generate heat during operation.

12. The electronic device of claim 11, wherein the top housing member defines a plurality of pockets for receiving the plurality of fans, each pocket being positioned between an air vent and an air duct and configured to receive a respective fan.

13. The electronic device of claim 11, wherein the top housing member further includes sets of louvers that serve as air guides and fan protectors, each set of louvers being positioned proximate to an entry of an air vent.

14. The electronic device of claim 11, further comprising:
a fan cover plate positioned between the plurality of fans and the plurality of air ducts to maximize a flow of forced air from the plurality of fans into the plurality of air ducts.

15. The electronic device of claim 14, wherein the fan cover plate defines a plurality of apertures and wherein each aperture is sized and shaped to match a geometry of an output of a respective fan.

16. The electronic device of claim 11, wherein the plurality of air ducts share a common exhaust port aligned with the fins of the heat sink.

17. The electronic device of claim 11, wherein each of the plurality of fans is positioned so as to draw air in vertically through a respective air vent and force air out vertically into a respective air duct.

18. The electronic device of claim 11, wherein each of the plurality of air ducts is configured to receive air from a first direction and direct the received air in a second direction that is not collinear with the first direction.

19. The electronic device of claim 18, wherein the second direction is substantially orthogonal to the first direction.

20. An electronic device comprising:
a top housing member including an air vent and a fan pocket adjacent to the air vent;
a bottom housing member including a floor portion and a finned heat sink, the floor portion including an air duct to direct air over fins of the heat sink, wherein the fins are externally exposed on an outside surface of the bottom housing member;
a fan positioned in the fan pocket between the air vent and the air duct, the fan operable to draw air in through the air vent and force air out into the air duct for flow over and along the fins of the heat sink; and
at least one electrical module thermally coupled to a base of the heat sink and operable to generate heat during operation.
